(19) United States
(12) Patent Application Publication
(10) Pub. No.: US 2007/0224825 A1
(43) Pub. Date: Sep. 27, 2007

(54) METHODS FOR ETCHING A BOTTOM ANTI-REFLECTIVE COATING LAYER IN DUAL DAMASCENE APPLICATION

(76) Inventors: Ying Xiao, San Jose, CA (US); Gerardo A. Delgadino, Santa Clara, CA (US); Karsten Schneider, Dresden (DE)

Correspondence Address: PATTERSON & SHERIDAN, LLP, 3040 POST OAK BOULEVARD, SUITE 1500, HOUSTON, TX, 77056, US

(21) Appl. No.: 11/617,946

(22) Filed: Dec. 29, 2006

Related U.S. Application Data
(63) Continuation of application No. 11/388,232, filed on Mar. 22, 2006.

(51) Int. Cl. H01L 21/311; H01L 21/461

(52) U.S. Cl. 438/700; 438/706; 438/710; 438/714

(57) ABSTRACT

Methods for two step etching a BARC layer in a dual damascene structure are provided. In one embodiment, the method includes providing a substrate having vias filled with a BARC layer disposed on the substrate in an etch reactor, supplying a first gas mixture into the reactor to etch a first portion of the BARC layer filling in the vias, and supplying a second gas mixture comprising NH₃ gas into the reactor to etch a second portion of the BARC layer disposed in the vias.

### CROSS-REFERENCE TO RELATED APPLICATION

This application is a continuation of U.S. patent application Ser. No. 11/388,232, filed Mar. 22, 2006 (Attorney Docket No. APPM/10213), which is incorporated by reference in its entirety.

### BACKGROUND OF THE INVENTION

1. Field of the Invention

The present invention generally relates to semiconductor processing technologies and, more specifically, to methods for etching a bottom anti-reflective coating (BARC) layer in a dual damascene etching processing.

2. Description of the Related Art

Integrated circuits have evolved into complex devices that can include millions of components (e.g., transistors, capacitors and resistors) on a single chip. The evolution of chip designs continually requires faster circuitry and greater circuit density. The demands for greater circuit density necessitate a reduction in the dimensions of the integrated circuit components.

As the dimensions of the integrated circuit components are reduced (e.g. sub-micron dimensions), the materials used to fabricate such components contribute to their electrical performance. For example, metal interconnects with low resistance (e.g., copper and aluminum) provide conductive paths between the components on integrated circuits.

Typically, the metal interconnects are electrically isolated from each other by a dielectric bulk insulating material. When the distance between adjacent metal interconnects and/or the thickness of the dielectric bulk insulating material has sub-micron dimensions, capacitive coupling potentially occurs between such interconnects. Capacitive coupling between adjacent metal interconnects may cause cross talk and/or resistance-capacitance (RC) delay which degrades the overall performance of the integrated circuit.

Some integrated circuit components include multilevel interconnect structures (e.g., dual damascene structures). Typically, dual damascene structures have dielectric bulk insulating layers and conductive layers, such as copper, stacked on top of one another. Vias and/or trenches are etched into the dielectric bulk insulating layer and copper conductive layers are subsequently filled into the vias and/or trenches and polished back using a process such as chemical mechanical planarization (CMP), so the conducting materials are only left in the vias and/or trenches. In the dual damascene approach, both vias and trenches are patterned into a layer of dielectric material or a stack of different dielectric materials before copper.

Different processing sequences of etching vias and/or trenches in dielectric materials can be used in a dual damascene process. As an exemplary embodiment shown in FIG. 1A, a “via-first” processing sequence for etching vias and/or trenches is illustrated. Vias 128, 130 are formed in a dielectric stack 132 disposed on a substrate 102. The dielectric stack 132 has a first region 116 having low feature density (e.g. isolated vias 130) and a second region 118 having high feature density (e.g., dense vias 128). The dielectric stack 132 includes a polish stop layer 110 and a dielectric bulk insulating layer 108 disposed on a dielectric barrier layer 106. A copper line 103 may be present in another dielectric stack or layer 104 disposed on the substrate 102 below the dielectric stack 132. The polish stop layer 110 and the dielectric barrier layer 106 are typically formed from a dielectric material, such as SiON, SiOC, SiN, SiCN, SiO₂, or the like. The dielectric bulk insulating layer 108 is typically formed from a dielectric material having a dielectric constant lower than 4.0, such as FSG, polymer material, carbon containing silicon layer (SiOC), and the like.

A bottom anti-reflective coating (BARC) layer 112 is spin-applied to fill the vias 128, 130 and cover the dielectric stack 132 before trench lithography. A hard mask layer 134 is deposited over the BARC layer 112 to serve as an etch mask layer. A hard mask etching process is performed to expose the underlying BARC layer 112 using a patterned photoresist layer 114. After the exposed hard mask layer 134 defined by the photoresist layer 114 has been etched away, a BARC etching process is performed to clear away a portion of the BARC layer 112 over the via opening 128, 130 by the hard mask layer 134 before etching the trenches. The spin-applied BARC layer 112, however, does not fill dense vias 128 and isolated vias 130 in a same manner. Typically, isolated vias 130 are filled more easily than dense vias 128, resulting in large variation in the BARC thickness between the first and second regions 116, 118 on top of the dielectric stack 132. As the BARC layer 112 at the via openings is etched away, portions of the underlying polish stop layer 110 defined by the hard mask layer 134 in dielectric stack 132 are exposed during the BARC etching process, as shown in FIG. 1B. Due to the different thickness of the BARC layer 112 on top of the dielectric stack 132, the BARC layer 112 over dense vias 128 are etched more than the portion of the BARC layer 112 over isolated vias 130. The non-uniform BARC layer 112 leads to non-uniform trench depth during a subsequent trench etching process. As shown in FIG. 1C, the BARC layer 112 is etched faster in the dense vias 128 relative to the BARC layer 112 in the isolated vias 130, resulting in the etched BARC layer 112 in the dense vias 128 becoming concave 120 while the BARC layer 112 in the isolated vias 130 remains insufficiently etch and/or remains surface 122 protruded over the vias 130.

FIG. 2A illustrates an exemplary structure of the BARC layer 112 with the protruded surface 122 over the isolated vias 130. The protruded surface 122 of the BARC layer 112 may create a shadowing effect, as further shown in FIG. 2B, causing portion of the dielectric bulk insulating layer 108 adjacent to BARC layer 112 to be etched at a slower rate than the other portions of the dielectric insulating layer 108. As such, when the hard mask layer 134 and the BARC layer 112 are stripped away, fence defects 126 are left in the trenches, as shown in FIG. 2C. Over etching and/or insufficient recess (or protrusion) of the BARC layer impacts the dimension and profile of the trenches and/or vias, resulting in degradation of the interconnect integration and deterioration of the electrical performance of the IC devices. Improvement in BARC etching can mitigate these effects.

Therefore, there is a need for a method of uniformly etching a BARC layer to form a desired dimension and profile of structures.

### SUMMARY OF THE INVENTION

Methods for two step etching of a BARC layer in a dual damascene structure are provided. In one embodiment, a method for etching a BARC layer in a dual damascene structure includes providing a substrate having vias filled with a BARC layer disposed on the substrate in an etch reactor, supplying a first gas mixture into the reactor to etch a first portion of the BARC layer filling in the vias, and supplying a second gas mixture comprising NH₃ gas into the reactor to etch a second portion of the BARC layer disposed in the vias.

In another embodiment, a method for etching a BARC layer in a dual damascene structure includes providing a substrate having a vias formed in a dielectric bulk insulating layer and filled with a BARC layer in an etch reactor, supplying a first gas mixture having N₂ and H₂ gas into the reactor to etch a portion of the BARC layer filling in the vias, and supplying a second gas mixture comprising NH₃, CO and O₂ gas into the reactor to etch the remaining portion of the BARC layer disposed in the vias to a predetermined depth.

In yet another embodiment, a method for etching a BARC layer in a dual damascene structure includes providing a substrate having vias formed in a dielectric bulk insulating layer and filled with a BARC layer in an etch reactor, wherein the BARC layer has a hard mask layer disposed thereover, supplying a gas mixture having a fluorine containing gas into the reactor to etch the hard mask layer using a patterned photoresist layer to expose a surface of the BARC layer, supplying a first gas mixture having N₂ and H₂ gas into the reactor to etch a portion of the BARC layer filling in the vias, and supplying a second gas mixture comprising NH₃, CO and O₂ gas, into the reactor to etch the remaining portion of the BARC layer in the vias to a predetermined depth.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIGS. 1A-1C are sectional views of an exemplary dual damascene structures with isolated and dense vias; and

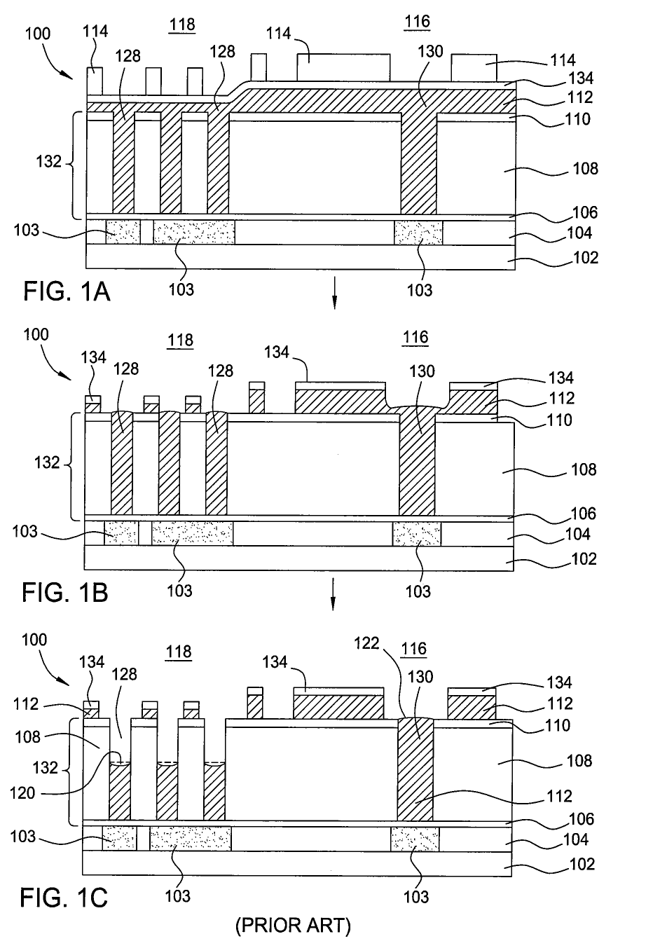

FIGS. 2A-2C are sectional views of another exemplary dual damascene structures;

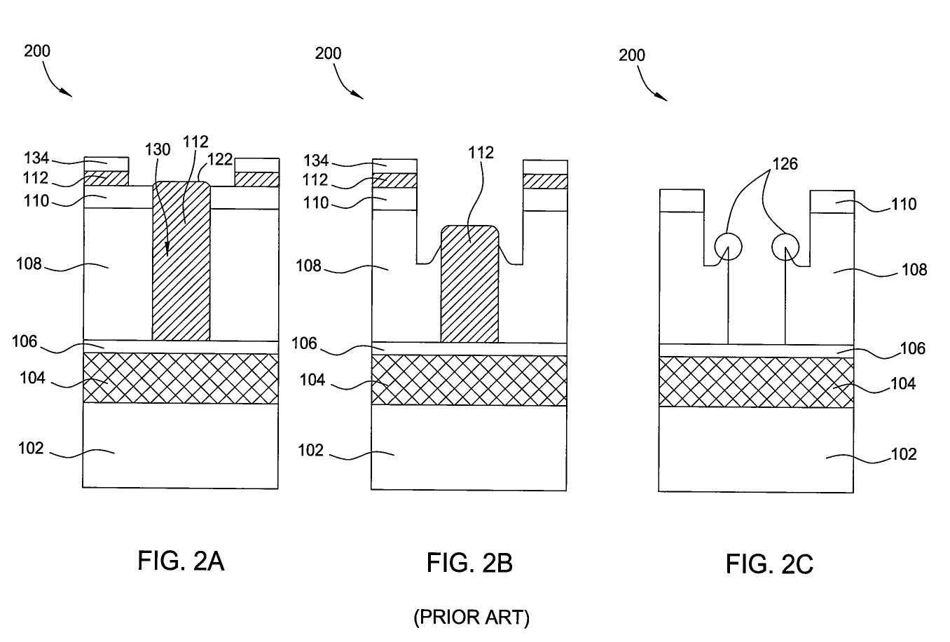

FIG. 3 is a schematic cross-sectional view of a plasma reactor used according to one embodiment of the invention;

FIG. 4 is a process flow diagram illustrating one embodiment of a method for two step etching method for etching a BARC layer in a dual damascene structure; and

FIGS. 5A-5D are sectional views of a dual damascene structure sequentially etched according to one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention include two step methods for etching a BARC layer in a dual damascene structure. The methods facilitate the profile and dimension of a BARC layer during a etching process, thereby enhancing the accuracy of trench formation in a dual damascene structure. The two step etching method includes supplying two different gas mixtures into an etch reactor to etch a BARC layer with good sidewall and/or surface protection, thereby minimizing profile variation associated with etching trenches having different pattern density.

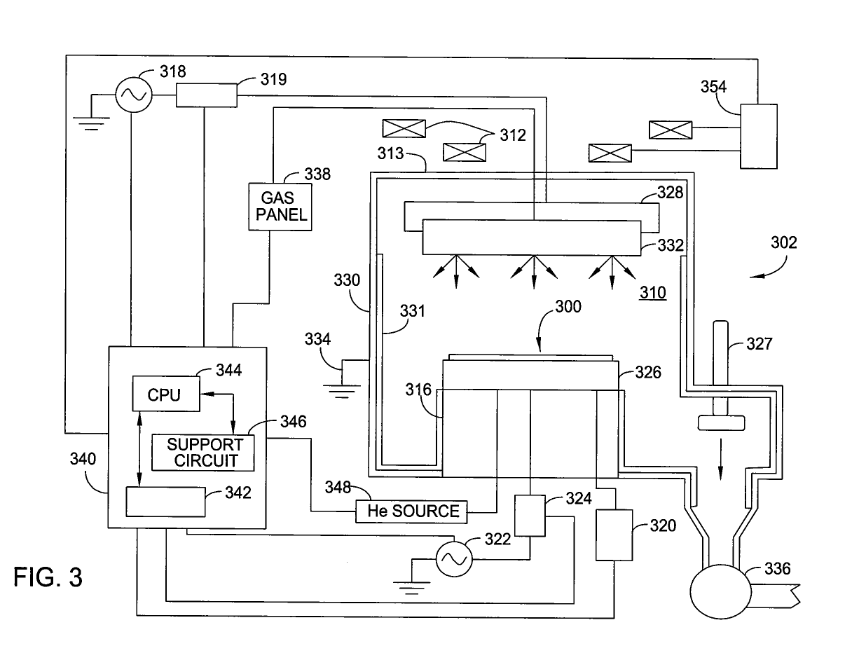

FIG. 3 depicts a schematic, cross-sectional diagram of one embodiment of a plasma source etch reactor 302 suitable for performing the present invention. One such etch reactor suitable for performing the invention is the ENABLERS processing chamber, available from Applied Materials, Inc., of Santa Clara, Calif. It is contemplated that the other etch reactors, including those from other manufactures, may be adapted to benefit from the invention.

In one embodiment, the reactor 302 includes a process chamber 310 having a conductive chamber wall 330. The temperature of the chamber wall 330 is controlled using liquid-containing conduits (not shown) that are located in and/or around the wall 330.

The chamber 310 is a high vacuum vessel that is coupled through a throttle valve 327 to a vacuum pump 336. The chamber wall 330 is connected to an electrical ground 334. A liner 331 is disposed in the chamber 310 to cover the interior surfaces of the walls 330. The liner 331 facilitates the cleaning capabilities of the chamber 310.

The process chamber 310 also includes a support pedestal 316 and a showerhead 332. The support pedestal 316 supports a substrate 300 below the showerhead 332 in a spaced-apart relation during processing. The support pedestal 316 may include an electrostatic chuck 326 for retaining the substrate 300. Power to the electrostatic chuck 326 is controlled by a DC power supply 320.

The support pedestal 316 is coupled to a radio frequency (RF) bias power source 322 through a matching network 324. The bias power source 322 is generally capable of producing an RF signal having a tunable frequency of from about 50 kHz to about 60 MHz and a bias power of about 0 to 5,000 Watts. Optionally, the bias power source 322 may be a DC or pulsed DC source.

The temperature of the substrate 300 supported on the support pedestal 316 is at least partially controlled by regulating the temperature of the support pedestal 316. In one embodiment, the support pedestal 316 includes a cooling plate (not shown) having channels formed therein for flowing a coolant. In addition, a backside gas, such as helium (He) gas from a gas source 348, is provided into channels disposed between the back side of the substrate 300 and grooves (not shown) formed in the surface of the electrostatic chuck 326. The backside He gas provides efficient heat transfer between the pedestal 316 and the substrate 300. The electrostatic chuck 326 may also include a resistive heater (not shown) within the chuck body to heat the chuck 326. In one embodiment, the substrate 300 is maintained at a temperature of between about 10 to about 500 degrees Celsius.

The showerhead 332 is mounted to a lid 313 of the processing chamber 310. A gas panel 338 is fluidly coupled to a plenum (not shown) defined between the showerhead 332 and the lid 313. The showerhead 332 includes a plurality of holes to allow gases, provided to the plenum from the gas panel 338, to enter the process chamber 310. The holes in the showerhead 332 may be arranged in different zones such that various gases can be released into the chamber 310 with different volumetric flow rates.

The showerhead 332 and/or an upper electrode 328 positioned proximate thereto is coupled to an RF source power 318 through an impedance transformer 319 (e.g., a quarter wavelength matching stub). The RF source power 318 is generally capable of producing an RF signal having a tunable frequency of about 160 MHz and a source power of about 0 to 5,000 Watts.

The reactor 302 may also include one or more coil segments or magnets 312 positioned exterior to the chamber wall 330, near the chamber lid 313. Power to the coil segment(s) 312 is controlled by a DC power source or a low-frequency AC power source 354.

During processing, gas pressure within the interior of the chamber 310 is controlled using the gas panel 338 and the throttle valve 327. In one embodiment, the gas pressure within the interior of the chamber 310 is maintained at about 0.1 to 999 mTorr.

A controller 340, including a central processing unit (CPU) 344, a memory 342, and support circuits 346, is coupled to the various components of the reactor 302 to facilitate control of the processes of the present invention. The memory 342 can be any computer-readable medium, such as random access memory (RAM), read only memory (ROM), floppy disk, hard disk, or any other form of digital storage, local or remote to the reactor 302 or CPU 344. The support circuits 346 are coupled to the CPU 344 for supporting the CPU in a conventional manner. These circuits include cache, power supplies, clock circuits, input/output circuitry and subsystems, and the like. A software routine or a series of program instructions stored in the memory 342, when executed by the CPU 344, causes the reactor 302 to perform processes of the present invention.

FIG. 3 only shows one exemplary configuration of various types of plasma reactors that can be used to practice the invention. For example, different types of source power and bias power can be coupled into the plasma chamber using different coupling mechanisms. Using both the source power and the bias power allows independent control of a plasma density and a bias voltage of the substrate with respect to the plasma. In some applications, the source power may not be needed and the plasma is maintained solely by the bias power. The plasma density can be enhanced by a magnetic field applied to the vacuum chamber using electromagnets driven with a low frequency (e.g., 0.1-0.5 Hertz) AC current source or a DC source. In other applications, the plasma may be generated in a different chamber from the one in which the substrate is located, e.g., remote plasma source, and the plasma subsequently guided into the chamber using techniques known in the art.

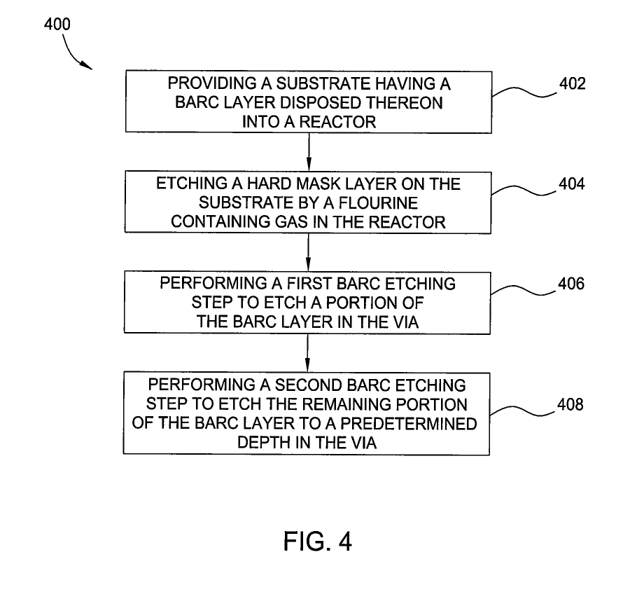

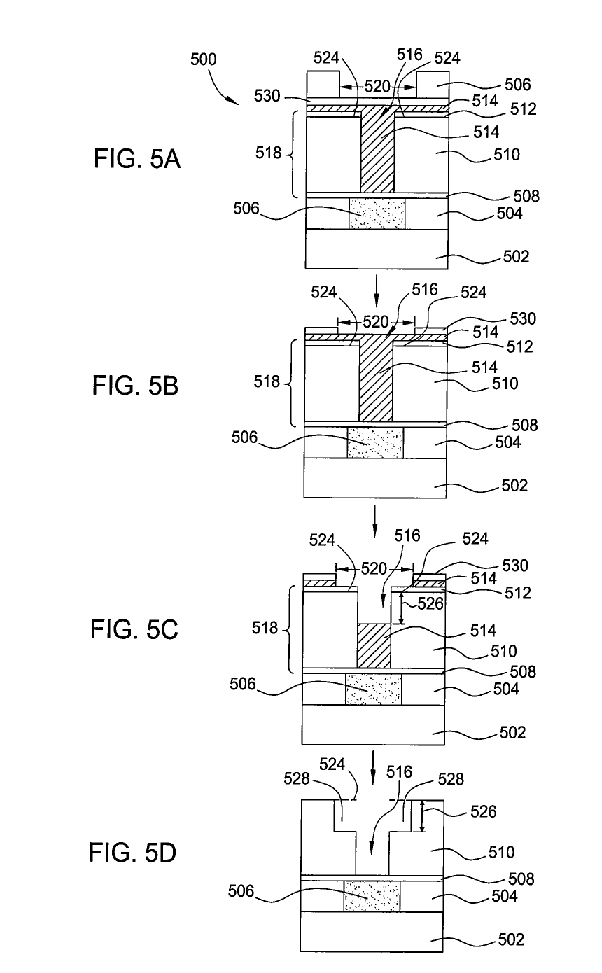

FIG. 4 illustrates a flow diagram of one embodiment of a BARC etching process 400 in a dual damascene structure according to one embodiment of the invention. FIGS. 5A-5D are schematic cross-sectional views corresponding to different stages of process 400 illustrating the BARC etching process 400. The process 400 may be stored in memory 342 as instructions, that when executed by the controller 340, cause the process 400 to be performed in the reactor 302.

The process 400 begins at step 402 by providing a substrate having a dual damascene structure in the reactor 302. FIG. 5A shows a dual damascene structure having a dielectric stack 518 disposed on a layer 504 formed on a substrate 502. The layer 504 has at least one conductive layer 506, such as copper line, disposed therein. The dielectric stack 518 may include a polish stop layer 512 and a dielectric bulk insulating layer 510 disposed over an optional dielectric barrier layer 508. In embodiments the optional dielectric barrier layer 508 not present, the dielectric bulk insulating layer 510 may be directly disposed on the underlying layer 504. A via 516 is formed in the dielectric bulk insulating layer 510 and the polish stop layer 512 by a conventional etching process. In one embodiment, the dielectric bulk insulating layer 510 is a dielectric material having a dielectric constant less than 4.0. Examples of suitable materials include carbon-containing silicon oxides (SiOC), such as BLACK DIAMOND® dielectric material available from Applied Materials, Inc., and other polymers, such as polyamides.

A BARC layer 514 fills the vias 516 and covers the dielectric stack 518. The BARC layer 514 is used to control reflections from the underlying dielectric layer and/or stack during lithography. The BARC layer 514 may comprise, for example, organic materials such as polyamides and polysulfones typically having hydrogen and carbon containing elements, or inorganic materials such as silicon nitride, silicon oxynitride, silicon carbide, and the like. In the embodiment depicted in FIG. 5A, the BARC layer 514 is an organic material spun-on the substrate 502 to fill the vias 516 before trench lithography. In another exemplary embodiment, the BARC layer 514 may be coated, deposited, or filled in the vias in any other suitable manner.

A hard mask layer 530 may be disposed over the BARC layer 514 to serve as a etch mask during trench etching. In one embodiment, the polish stop layer 512 is a dielectric layer, such as SiO₂, SiON, SiN, SiOCN, SiCN, or the like. In the embodiment depicted in FIG. 5A, the hard mask layer 530 is a SOG layer spin-applied on the BARC layer 514.

The polish stop layer 512 may be disposed over the dielectric bulk insulating layer 510. In one embodiment, the hard mask layer 512 is a dielectric layer, such as SiO₂, SiON, SiN, SiOCN, SiCN, or the like. In embodiments that the polish stop layer 512 is not present, the BARC layer 514 may directly dispose on and cover a portion 524 (e.g. a surface) of the dielectric bulk insulating layer 510.

The optional dielectric barrier layer 508 is selected from a material having a dielectric constant of about 5.5 or less. In one embodiment, the dielectric barrier layer 406 is a carbon containing silicon layer (SiC), a nitrogen doped carbon containing silicon layer (SiCN), or the like.

A photoresist layer 506 is disposed on the hard mask layer 530 to transfer a predetermined pattern and/or feature into the dielectric stack 518 through an etching process. The patterned photoresist layer 506 may comprise a conventional carbon-based, organic or polymeric materials used to pattern integrated circuit. In the embodiment depicted in FIG. 5A, the hard mask layer 530 and/or the BARC layer 514 disposed below the photoresist layer 506 is etched through an opening 520 defined by the photoresist layer 506 to form a trench over the via 516 in the dielectric stack 518.

At step 404, a hard mask etching process is performed to etch the hard mask layer 530 exposed in the opening 520. During etching, the hard mask layer 530 in the opening 520 may be removed until an upper surface of the underlying BARC layer 514 is exposed, as shown in FIG. 5B. Typically, the photoresist layer 506 is etched away during the hard mask etching step, thereby leaving the hard mask layer 530 as an remaining etching mask for the subsequently etching process. The hard mask etch process is terminated either after a predetermined time period or by a conventional optical endpoint measurement technique that determines, by monitoring emissions from the plasma, whether portions of the underlying BARC layer 514 in the opening 520 have become exposed to the plasma.

In one embodiment, the hard mask layer 530 may be etched using a plasma formed from a fluorine containing gas mixture. Examples of suitable fluorine containing gases include, but not limited to, CF₄, CHF₃, C₂F₆, C₃F₈, CF₆, C₄F₈, C₅F₈, C₄F₆, NF₃, SF₆ and the like. In another embodiment, the hard mask layer 530 is etched using a plasma formed from a fluorine containing gas mixture that includes at least one of O₂, N₂, Ar, He, an insert gas, and the like. The hard mask layer 530 may be etched in an etch chamber, such as the reactor 302 described in FIG. 3, or in other suitable reactors.

In one embodiment, the hard mask etch process may be performed by supplying a gas mixture of fluorine containing gas, such as CF₄ and CHF₃, into the etch reactor, applying a power between about 300 Watt to about 2000 Watt, maintaining a temperature between about 0 degrees Celsius to about 60 degrees Celsius, and controlling process pressure between about 10 to about 300 mTorr into the reactor. The CF₄ gas may be supplied at a flow rate between about 5 sccm to about 300 sccm. The CHF₃ gas may be supplied at a flow rate between about 5 sccm to about 300 sccm. In another embodiment, at least one insert gas, such as O₂, may also be supplied with the fluorine containing gas mixture into the reactor. The O₂ gas may be supplied at a flow rate between about 0 to about 100 sccm.

At step 406, a first BARC etching step is performed to initially etch a portion of the BARC layer 514 filling the via 516 by supplying a first gas mixture in the reactor 302. In one embodiment, the first gas mixture supplied into the reactor 302 contains hydrogen gas (H₂) and nitrogen gas (N₂). The first gas mixture is also used to purge and flush out the residual gas, e.g, fluorine containing gas, from the previous step 404 remaining in the reactor 302, thereby preventing defect generation or chemical reaction with residual fluorine chemistry in the following etching steps.

In one embodiment, the BARC layer 514 is first etched by forming a plasma from the first gas mixture containing H₂ gas and N₂ gas. The BARC layer 514 may be etched in an etch chamber, such as the reactor 302 described in FIG. 3, or in other suitable reactors.

Several process parameters are regulated at step 406 while the first gas mixture is supplied into the reactor 302. In one embodiment, a pressure of the gas mixture in the etch reactor is regulated between about 5 mTorr to about 200 mTorr, and the substrate temperature is maintained between about 0 degrees Celsius and about 60 degrees Celsius. RF source power may be applied at a power of about 300 Watts to about 2000 Watts. The H₂ gas may be flowed at a flow rate between about 5 sccm to about 200 sccm. The N₂ gas may be flowed at a flow rate between about 5 sccm to about 200 sccm.

In one embodiment, the first BARC etching step may be terminated by expiration of a predefined time period. For example, the first BARC etching step is terminated by processing between about 5 second to about 50 second. In another embodiment, the first BARC etching step may be terminated by other suitable method including monitoring optical emission or by another indicator.

At step 408, a second BARC etching step is performed to etch the remaining portion of the BARC layer 514 filling the via 516 into a predetermined depth, as shown in FIG. 5C. The second BARC layer etching step 408 is performed using a second gas mixture supplied into the reactor 302. In one embodiment, the gas mixture includes NH₃ gas. In another embodiment, the second gas mixture includes NH₃ gas and an oxygen containing gas. Suitable oxygen containing gases include CO and O₂. The second BARC etching step is terminated by expiration of a predefined time period, monitoring optical emissions or by another indicator that determines that the BARC layer 514 is recessed a predetermined depth 526 below the surface 524 of the dielectric bulk insulating layer 510. In one embodiment, the predetermined depth 526 of the BARC layer 514 recessed below the surface 524 of the dielectric bulk insulating layer 510 is about 0 nm to about 200 nm.

In one embodiment, the BARC layer 514 is etched by forming a plasma from the second gas mixture containing NH₃ gas and an oxygen containing gas, such as CO and/or O₂. In another embodiment, the BARC layer 514 is etched by forming a plasma from the second gas mixture containing NH₃, CO and O₂. The BARC layer 514 may be etched in an etch chamber, such as the reactor 302 described in FIG. 3, or in other suitable reactors.

Several process parameters are regulated at step 408 while the second gas mixture is supplied into the reactor 302. In one embodiment, a pressure of the gas mixture in the etch reactor is regulated between about 5 mTorr to about 200 mTorr, and the substrate temperature is maintained between about 0 degrees Celsius and about 60 degrees Celsius. RF source power may be applied at a power of about 300 Watts to about 2000 Watts. The NH₃ gas may be flowed at a flow rate between about 5 sccm to about 300 sccm. The O₂ gas may be flowed at a flow rate between about 5 sccm to about 200 sccm. The CO gas may be flowed at a flow rate between about 5 sccm to about 500 sccm. The etching time may be processed at between about 20 seconds to about 100 seconds.

During the second BARC etching step, the NH₃ gas supplied with the second gas mixture reacts with the BARC layer 514, forming a protective polymer on the surface and/or sidewall of the BARC layer 514. As the BARC layer 514 in the dense vias is etched faster relative to the BARC layer 514 in isolated vias, a relatively higher amount of the protective polymer may be accumulated over the BARC layers 514 in dense vias than in the isolated vias. The accumulated protective polymer in dense vias prevents the BARC layer 514 from etched while the BARC layer 514 in isolated vias remains sequentially etched until a predetermined depth is reached. The differential etch rate associated with the pattern density of the substrate is minimized by the different amount of accumulated protective polymer in dense and isolated vias. As such, a substantially uniform etching profile can be achieved in both regions having isolated and dense vias, thereby preventing the defects, e.g. fence or BARC layer concave, associated with via pattern density variation in conventional etch processes.

Subsequently, several etching process including etching the polish stop layer 512, dielectric insulating layer 510 from the opening surface 524 to the predetermined depth 526 may be performed to form a trench 528 as needed. After the trenches are formed, the remaining BARC layer 514, or the hard mask layer 530 may be stripped or removed from the substrate by any suitable method to form a dual damascene structure, as shown in FIG. 5D.

Thus, the present invention provides a two step etching method for etching a BARC layer with a uniform etching profile. The method advantageously facilitates the profile and dimension of trenches and/or vias in both the isolated and dense vias in a dual damascene structure by supplying different gas mixtures to two step etch the BARC layer with sufficient sidewall and/or surface protection.

While the foregoing is directed to embodiments of the present invention, other and further embodiments of the invention may be devised without departing from the basic scope thereof, and the scope thereof is determined by the claims that follow.

What is claimed is:

1. A method for etching a BARC material, comprising:
providing a substrate in an etch reactor, the substrate having vias formed in a dielectric layer and filled with a BARC material disposed on the substrate;
etching the BARC material in the presence of a first gas mixture through a patterned hardmask to a first elevation defined between a top surface and a bottom surface of the dielectric layer; and
subsequently etching the BARC material in the presence of a second gas mixture comprising NH₃ gas.

2. The method of claim 1, wherein the step of etching in the presence of the first gas mixture further comprises:
flowing N₂ and H₂ into the reactor.

3. The method of claim 2, wherein the step of flowing N₂ and H₂ further comprises:
flowing N₂ at a rate between about 5 sccm to about 200 sccm; and
flowing H₂ at a rate between about 5 sccm to about 200 sccm.

4. The method of claim 1, wherein the step of etching in the presence of the first gas mixture further comprises:
maintaining a process pressure at between about 5 mTorr to about 200 mTorr;
controlling substrate temperature between about 0 degrees Celsius to about 60 degrees Celsius; and
applying a plasma power at between about 300 Watts to about 2000 Watts.

5. The method of claim 1, wherein the step of etching in the presence of the second gas mixture further comprises:
flowing at least one of CO and O₂ into the reactor.

6. The method of claim 1, wherein the step of etching in the presence of the second gas mixture further comprises:
flowing NH₃ at a rate between about 5 sccm to about 300 sccm.

7. The method of claim 5, wherein the step of flowing the second gas mixture further comprises:
flowing CO at a rate between about 5 sccm to about 500 sccm; and
flowing O₂ at a rate between about 5 sccm to about 200 sccm.

8. The method of claim 1, wherein the step of etching in the presence of the second gas mixture further comprises:
maintaining a process pressure at between about 5 mTorr to about 200 mTorr;
controlling substrate temperature between about 0 degrees Celsius to about 60 degrees Celsius; and
applying a plasma power at between about 300 Watts to about 2000 Watts.

9. The method of claim 1, further comprising:
patterning the hard mask layer using a fluorine containing gas prior to etching the BARC material.

10. The method of claim 9, further comprising:
purging out the residual fluorine containing gas in the reactor by the first gas mixture.

11. The method claim 9, wherein the fluorine containing gas is selected from a group consisting of CF₄, CHF₃, C₂F₆, C₃F₈, C₄F₈, C₅F₈, C₄F₆, SF₆ and NF₃.

12. A method for etching a BARC material, comprising:
providing a substrate having vias formed in a dielectric bulk insulating layer and filled with a BARC material in an etch reactor, the substrate having a patterned hardmask layer disposed thereon;
supplying a first gas mixture having N₂ and H₂ gas into the reactor to etch the BARC material filling in the vias to an elevation defined within a thickness of the dielectric bulk insulating layer; and
subsequently supplying a second gas mixture comprising NH₃, CO and O₂ gas, into the reactor to etch the BARC material in the vias to a predetermined depth.

13. The method claim 12, wherein the step of proving a substrate further comprising:
flowing a gas mixture having a fluorine containing gas into the reactor to pattern the hardmask prior to etching the BARC material.

14. The method of claim 13, wherein the step of supplying the first gas mixture further comprising:
flowing the N₂ gas at a rate between about 5 sccm to about 200 sccm; and
flowing the H₂ gas at a rate between about 5 sccm to about 200 sccm.

15. The method of claim 12, wherein the step of supplying the second gas mixture further comprising:
flowing the NH₃ gas at a rate between about 5 sccm to about 300 sccm;
flowing the CO gas at a rate between about 5 sccm to about 500 sccm; and
flowing the O₂ gas at a rate between about 5 sccm to about 200 sccm.

16. The method of claim 12, wherein the step of supplying a second gas mixture further comprises:
reacting with the BARC material by the second gas mixture to form a polymer protection on sidewall or surface of the BARC material.

17. A method for etching a BARC material, comprising:
providing a substrate having vias formed in a dielectric bulk insulating layer and filled with a BARC material in an etch filled with a BARC material in an etch reactor, wherein the BARC material has a hard mask layer disposed thereover;
supplying a gas mixture having fluorine containing gas into the reactor to etch the hard mask layer using a patterned photoresist layer to expose a surface of the BARC material;
supplying a first gas mixture having N₂ and H₂ gas into the reactor to etch a portion of the BARC material filling in the vias to an elevation defined within a thickness of the dielectric bulk insulating layer; and
subsequently supplying a second gas mixture comprising NH₃, CO and O₂ gas, into the reactor to etch the BARC material in the vias to a predetermined depth.
